(19) United States
(12) Patent Application Publication
(10) Pub. No.: US 2009/0027145 A1
(43) Pub. Date: Jan. 29, 2009

(54) RECEIVER COMPRISING TWO TUNNERS

(75) Inventors: Kui Yong Lim, Singapore (SG); Joe Kok Keen Leong, Singapore (SG)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/162,162

(22) PCT Filed: Jan. 22, 2007
(86) PCT No.: PCT/IB07/50205

§ 371 Date: Jul. 25, 2008

(30) Foreign Application Priority Data
Jan. 27, 2006 (EP) 06100971.8

(51) Int. Cl. H03J 7/08

(52) U.S. Cl. 334/11

(57) ABSTRACT

A receiver comprises two tuners and a DC-to-DC converter (DCC) for generating an increased supply voltage (VH) on the basis of a main supply voltage. Each tuner comprises a tunable circuit (TUC1), which can be tuned by means of a tuning voltage (VT1). Each tuner further comprises a tuning control circuit (TCC1) that is coupled to the DC-to-DC converter (DCC) via a load circuit (LD1) for generating the tuning voltage (VT1). The load circuit (LD1) of at least one of the two tuners comprises a branch (D1) coupled to receive the main supply voltage (VCC). The branch (D1) is conductive when the tuning voltage (VT1) is within a voltage range substantially comprised between 0 and the main supply voltage (VCC).

### FIELD OF THE INVENTION

An aspect of the invention relates to a receiver that comprises two tuners. The receiver may be, for example, a television receiver capable of providing a picture-in-picture image. Another example is a set-top box with a tuner for receiving a channel that is rendered and another tuner for simultaneously recording another channel. Another aspect of the invention relate to an audiovisual set.

### DESCRIPTION OF PRIOR ART

European patent number 0 739 535 describes a tuning system in which a DC-to-DC converter provides a tuning control voltage for a tuner. The DC-to-DC converter is in the form of a series arrangement of an AC source, an inductive element and a rectifier circuit. The AC signal provided by the AC source is controlled by a tuning error signal from a tuning detector circuit. The inductive element transforms this AC signal into an AC signal of higher amplitude. The latter AC signal is rectified to provide the tuning control voltage. In effect, the DC-to-DC converter is part of a tuning control loop. This tuning control loop determines the output voltage of the DC-to-DC converter.

### SUMMARY OF THE INVENTION

According to an aspect of the invention, a receiver comprises two tuners and a DC-to-DC converter for generating an increased supply voltage on the basis of a main supply voltage. Each tuner comprises a tunable circuit, which can be tuned by means of a tuning voltage. Each tuner further comprises a tuning control circuit that is coupled to the DC-to-DC converter via a load circuit for generating the tuning voltage. The load circuit of at least one of the two tuners comprises a branch coupled to receive the main supply voltage. The branch is conductive when the tuning voltage is within a voltage range substantially comprised between 0 and the main supply voltage.

The invention takes the following aspects into consideration. A tuner is typically tuned by means of a tuning voltage that is applied to one or more varactors, or other voltage-dependent impedances, within the tuner. The tuning voltage may need to be higher than a main supply voltage within a receiver of which the tuner forms part. For example, the tuning voltage may need to be varied within a range comprised between 0 and 28 volts, whereas the main supply voltage is 5 volts only. In such a case, a DC-to-DC converter can be used to allow the tuning voltage to have a value that is above the main supply voltage.

In a receiver that comprises two tuners, using a single DC-to-DC converter for generating respective tuning voltages in the two tuners allows small-size and low-cost implementations. In such an implementation, each tuner may have a load circuit via which the tuner draws a load current from the DC-to-DC converter. A tuning voltage results from a voltage drop within the load circuit. The lower the tuning voltage is, the higher the load current is that the DC-to-DC converter needs to provide.

A tuning problem may occur in the receiver described hereinbefore, which uses a single DC-to-DC converter for two tuners, one of which will be called tuner A, the other tuner B. Let it be assumed that tuner A is tuned to a channel for which the tuning voltage has a relatively low value. Tuner A will draw a relatively large load current from the DC-to-DC converter. The DC-to-DC converter has a given power supply capability. The relatively large load current that tuner A draws may exceed the power supply capability of the DC-to-DC converter and, as a result, significantly pull down the increased supply voltage. Let it further be assumed that tuner B needs to be tuned to a channel for which the tuning voltage needs to have a relatively high value. The relatively large load current that tuner A draws from the DC-to-DC converter, may cause the increased supply voltage to drop below the relatively high value that the tuning voltage of tuner B needs to have. In such a case, tuner B cannot be correctly tuned because the tuning voltage cannot exceed the increased supply voltage that the DC-to-DC converter provides.

In accordance with the aforementioned aspect of the invention, the load circuit of at least one tuner comprises a branch coupled to receive the main supply voltage. The branch is conductive when the tuning voltage is within a voltage range substantially comprised between 0 and the main supply voltage.

Accordingly, a load current is at least partially drawn from the main supply voltage if the tuning voltage is relatively low. This prevents the DC-to-DC converter from having to provide a relatively large output current if the tuning voltage is relatively low. The increased supply voltage will therefore be pulled down to a lesser extent compared with an implementation in which load currents are entirely drawn from the DC-to-DC converter, irrespective of tuning voltage values. The invention can thus prevent that a tuning problem as described hereinbefore occurs. For those reasons, the invention allows greater reliability.

Another advantage of the invention relates to the following aspects. In principle, it is possible to solve the tuning problem described hereinbefore by increasing the power supply capability of the DC-to-DC converter. However, increasing the power supply capability of DC-to-DC converter generally necessitates increasing oscillation signal power within the DC-to-DC converter. A relatively high oscillation signal power may cause interference. Appropriate shielding may reduce interference, but this will generally be relatively expensive. The invention can prevent the tuning problem described hereinbefore without increasing the power supply capability of the DC-to-DC converter, or by increasing the power supply capability to a smaller extent than would otherwise be required in order to prevent the tuning problem. For those reasons, the invention allows interference-free implementations and low-cost implementations.

These and other aspects of the invention will be described in greater detail hereinafter with reference to drawings.

### BRIEF DESCRIPTION OF THE DRAWINGS

FIG. 1 is a block diagram that illustrates an audiovisual set.

FIGS. 2A and 2B are tables that illustrate tuning voltages within the audiovisual set.

FIG. 3 is a circuit diagram that illustrates details of a tuning control circuit and a load circuit that are involved in generating a tuning voltage within the audiovisual set.

### DETAILED DESCRIPTION

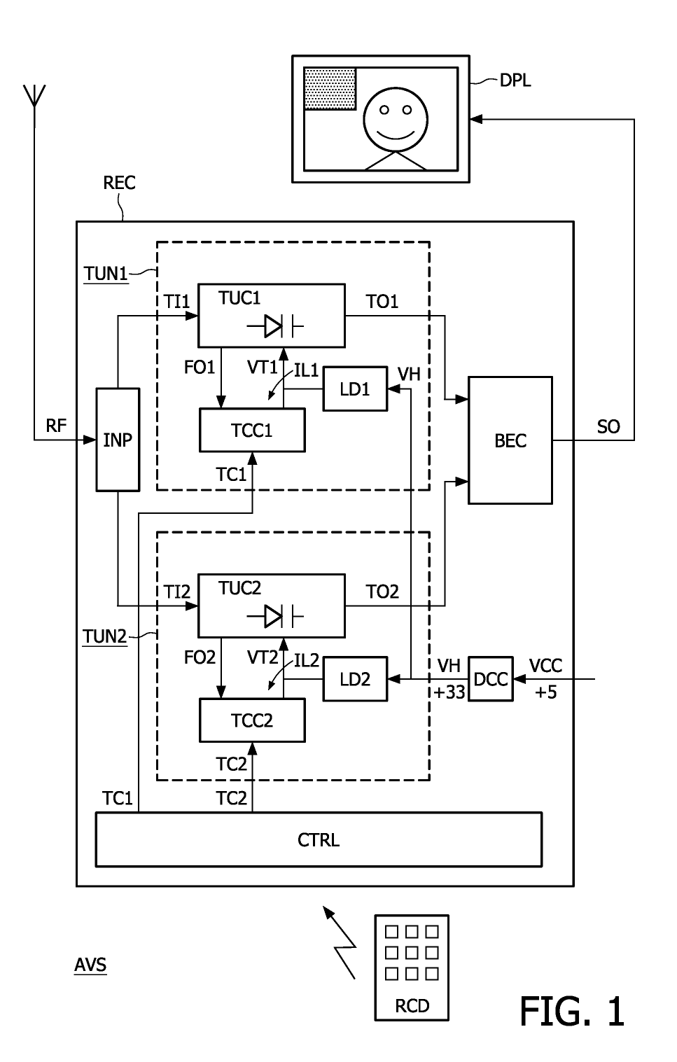

FIG. 1 illustrates an audiovisual set AVS. The audiovisual set AVS comprises a display device DPL, a receiver REC, and a remote control device RCD. The receiver REC derives an audiovisual signal SO from a radiofrequency spectrum RF, which comprises various different channels. The receiver REC is a so-called double tuner receiver. Consequently, the audiovisual signal SO may be composition of video signals or audio signals, or both, which are comprised in two different channels. The display device DPL renders the audiovisual signal SO. FIG. 1 illustrates that the display device DPL displays a picture-in-picture image, which comprises a main picture and a sub picture. The main picture may be based on, for example, a channel A and the sub picture may be based on a channel B.

The receiver REC comprises an input circuit INP, two tunable circuits TUC1, TUC2, two tuning control circuits TCC1, TCC2, two load circuits LD1, LD2, a backend circuit BEC, a DC-to-DC converter DCC, and a controller CTRL. Tunable circuit TUC1, tuning control circuit TCC1, and load circuit LD1 constitute a first tuner TUN1. Tunable circuit TUC2, tuning control circuit TCC2, and load circuit LD2 constitute a second tuner TUN2. The receiver receives a main supply voltage VCC from an electrical energy source, which may be, for example, a battery or a power supply that is coupled to a mains outlet. The main supply voltage VCC may be, for example, 5 volts.

The receiver REC basically operates as follows. The two tunable circuits TUC1, TUC2 receive tuner input signals TI1, TI2, respectively, from the input circuit INP. The tuner input signals TI1, TI2 comprise at least a portion of the radiofrequency spectrum RF, which the receiver REC receives. The input circuit INP may be, for example, a signal splitter with an all pass characteristic or a band pass characteristic so as to attenuate signals that lie outside a desired frequency band.

The two tunable circuits TUC1, TUC2 provide tuner output signals TO1, TO2 in response to tuner input signals TI1, TI2, respectively. Tuner output signal TO1 represents audiovisual information from a particular channel in the radiofrequency spectrum RF. Tuner output signal TO2 represents audiovisual information from another particular channel in the radiofrequency spectrum RF. That is, the two tunable circuits TUC1, TUC2 may be tuned to different channels within the radiofrequency spectrum RF. The backend circuit BEC, which receives the tuner output signals TO1, TO2, makes a composition of the audiovisual information in the tuner output signals TO1, TO2. The picture-in-picture image, which FIG. 1 illustrates, is an example of such a composition.

The two tunable circuits TUC1, TUC2 receive tuning voltages VT1, VT2, which are applied to electrically tunable elements such as, for example, varactors, within the two tunable circuits TUC1, TUC2, respectively. Accordingly, these tuning voltages VT1, VT2 determine the respective channels to which the two tunable circuits TUC1, TUC2 are tuned. The two tunable circuits TUC1, TUC2 can independently be tuned throughout a desired frequency band by varying tuning voltages VT1, VT2, respectively. The tuning voltages VT1, VT2 are comprised in a voltage range, which typically has a lower boundary of 0 volts and an upper boundary of 33 volts or higher.

Generating tuning voltage VT1 involves the following elements: tuning control circuit TCC1, load circuit LD1, and the DC-to-DC converter DCC. Generating tuning voltage VT2 involves the following elements: tuning control circuit TCC2, load circuit LD2, and the DC-to-DC converter DCC too. The DC-to-DC converter DCC thus participates in generating both tuning voltages VT1, VT2. The DC-to-DC converter DCC constitutes a DC voltage source that provides an increased supply voltage VH on the basis of the main supply voltage VCC. To that end, the DC-to-DC converter DCC may generate an oscillation signal of relatively large magnitude, which is rectified. The increased supply voltage VH may be, for example, 33 volts.

The two tuning control circuits TCC1, TCC2 receive oscillator frequencies FO1, FO2 from the two tunable circuits TUC1, TUC2 and tuning commands TC1, TC2 from the controller CTRL, respectively. Oscillator frequencies FO1, FO2 provide an indication of the channels to which the two tunable circuit TUC1, TUC2 are actually tuned, respectively. The tuning commands TC1, TC2 define the channels to which the two tunable circuits TUC1, TUC2 should be tuned, respectively. The controller CTRL provides the tuning commands TC1, TC2 on the basis of one or more channel selections that a user has entered on the remote control device RCD. Tuning control circuit TCC1 controls tuning voltage VT1 so that tunable circuit TUC1 is tuned to the channel that tuning command TC1 defines. Similarly, tuning control circuit TCC2 controls tuning voltage VT2 so that tunable circuit TUC2 is tuned to the channel that the tuning command TC2 defines.

More specifically, the two tuning control circuits TCC1, TCC2 provide load currents IL1, IL2 that flow through the two load circuits LD1, LD2, respectively. Load current IL1 flows through load circuit LD1, which causes a voltage drop within load circuit LD1. Similarly, load current IL2 flows through load circuit LD2 which causes a voltage drop within load circuit LD2. The lower tuning voltage VT1 needs to be, the greater load current IL1 needs to be. Similarly, the lower tuning voltage VT2 needs to be, the greater load current IL2 needs to be.

Let it be assumed a resistor, which has a given resistance value, forms load circuit LD1. In that case, tuning voltage VT1 is equal to the increased supply voltage VH, which the DC-to-DC converter DCC provides, minus load current IL1 multiplied by the given resistance value of the single resistor. The DC-to-DC converter DCC needs to provide load current IL1. The DC-to-DC converter DCC has a given power supply capability that is relatively low, which may cause the following phenomenon. The greater load current IL1 is, which the DC-to-DC converter DCC needs to provide, the lower the increased supply voltage VH will be. That is, a relatively high value of load current IL1 will pull down, as it were, the increased supply voltage VH. Load current IL1 has a relatively high value when tuning voltage VT1 is relatively small, such as, for example, 1 volt only. Consequently, a relatively low value of tuning voltage VT1 will pull down the increased supply voltage VH. There is a risk that the increased supply voltage VH drops below a critical level. The critical level can be defined as the highest value that tuning voltage VT2 may need to have for correctly tuning tunable circuit TUC2.

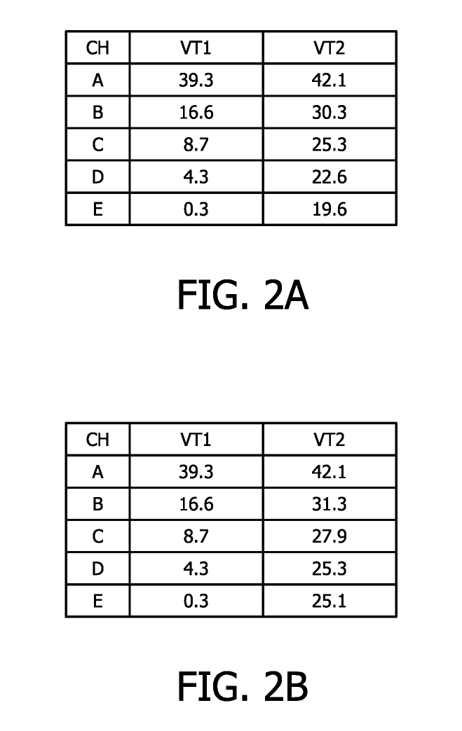

FIG. 2A illustrates the aforementioned phenomenon. FIG. 2A is a table with a left column that represents a channel CH to which tunable circuit TUC1 is tuned, a middle column that represents tuning voltage VT1 and a right column that represents tuning voltage VT2. The table is obtained while the receiver REC, which FIG. 1 illustrates, operates in a measurement mode. In the measurement mode, tuning control circuit TCC2 is deactivated so that load current IL2 is equal to zero. This means that tuning voltage VT2 is approximately equal to the increased supply voltage VH.

Tunable circuit TUC1 is tuned to five different channels named A, B, C, D, and E. The left-hand column illustrates that tuning voltage VT2 drops when tuning voltage VT1 drops. In case tunable circuit TUC1 is tuned to channel E for which tuning voltage VT1 is 0.3 volt, tuning voltage VT2 has dropped to a value of 19.6 volts. This means that tunable circuit TUC2 cannot be tuned to a channel that requires tuning voltage VT2 to have value that exceeds 19.6 volt when tunable circuit TUC1 is tuned to channel E. This may not be acceptable because, for example, tuning voltage VT2 needs to be 25 volt in order to tune tunable circuit TUC2 to a particular desired channel. Tunable circuit TUC2 cannot be tuned to that particular desired channel while tunable circuit TUC1 is tuned to channel E.

Increasing the power supply capability of the DC-to-DC converter DCC is an option to prevent a tuning problem as described hereinbefore. Increasing the power supply capability makes the increased supply voltage VH less dependent on load current IL1 and load current IL2 and, therefore, less dependent on tuning voltage VT1 and tuning voltage VT2. However, increasing the power supply capability generally necessitates increasing oscillation signal power within the DC-to-DC converter DCC. A relatively high oscillation signal power may cause interference. Appropriate shielding may reduce interference, but this will generally be relatively expensive. In summary, increasing the power supply capability of the DC-to-DC converter DCC may entail drawbacks in terms of interference or cost, or both.

Increasing the impedance of load circuit LD1 and load circuit LD2 seems another option to prevent a tuning problem as described hereinbefore. The lower the impedance of load circuit LD1 is, the lesser load current IL1 needs to be in order for tuning voltage VT1 to have a relatively low value and, consequently, the lesser the extent to which the increased supply voltage VH will drop. The same applies with respect to load circuit LD2 and tuning voltage VT2. However, the impedance of load circuit LD1 and the output impedance of the DC-to-DC converter DCC constitute a voltage divider, which determines a maximum value for tuning voltage VT1 in terms of a percentage of the increased supply voltage VH. Increasing the impedance of load circuit LD1 will therefore reduce the maximum value for tuning voltage VT1. The maximum value should be sufficiently high so that tunable circuit TUC1 can be tuned to any desired channel within a frequency band of interest. This condition is similar to the critical level for the increased supply voltage VH mentioned hereinbefore. The option which then remains is increasing the power supply capability of the DC-to-DC converter, which has been discussed hereinbefore. The invention provides a better option, which is described hereinafter.

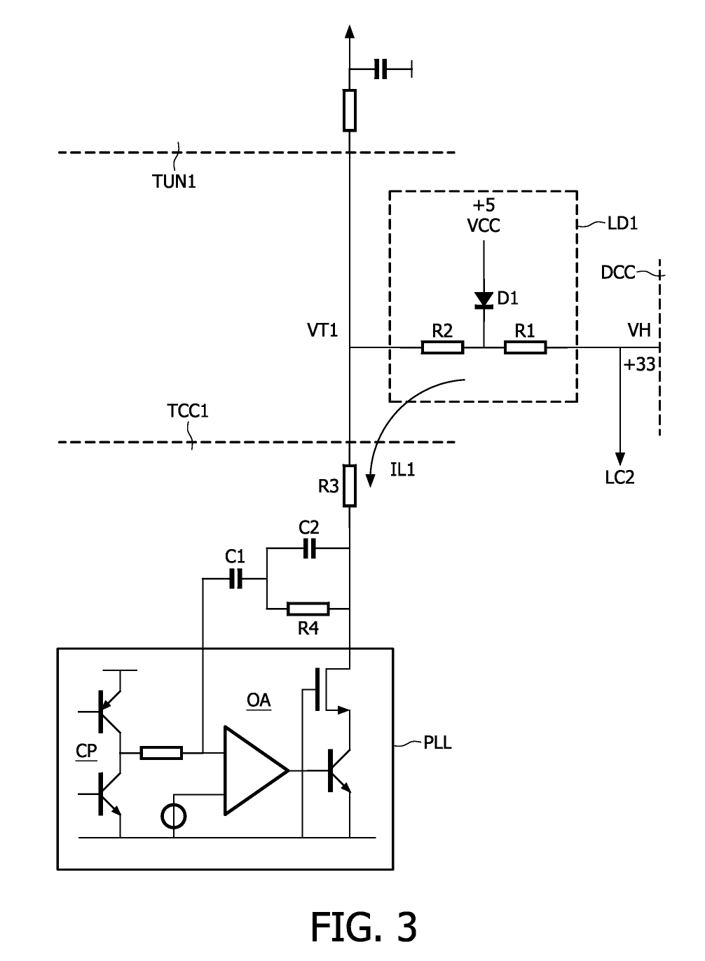

FIG. 3 illustrates details of load circuit LD1 and tuning control circuit TCC1. Load circuit LD1 comprises two resistances R1, R2, each of which has two terminals, and a diode D1, which has a cathode and anode. One terminal of resistance R1 receives the increased supply voltage VH. The other terminal is coupled to the cathode of the diode D1. One terminal of resistance R2 is also coupled to the cathode, the other terminal provides tuning voltage VT1. The anode of the diode D1 receives the main supply voltage VCC. Resistances R1, R2 may have a value of, for example, 39 kiloOhms (kΩ) and 3.9 kΩ, respectively. The diode D1 is preferably a so-called PIN diode (PIN is an acronym for P-type, Intrinsic, N-type).

Tuning control circuit TCC1 comprises a phaselock loop integrated circuit PLL, two capacitances C1, C2 and two resistances R3, R4. The phaselock loop integrated circuit PLL comprises a charge pump circuit CP and an amplifier circuit OA. The two capacitances C1, C2 and resistance R4, which are external to the phaselock loop integrated circuit PLL, constitute a feedback path for the amplifier circuit OA. The phaselock loop integrated circuit PLL may be a commercially available integrated circuit of a suitable type. Capacitances C1, C2 may have a value, for example, of 100 nanoFarad (nF) and 1.5 nF, respectively. Resistances R3, R4 may have a value of, for example, 15 kΩ and 100Ω, respectively.

Tuning control circuit TCC1 operates as follows. The amplifier circuit OA receives current pulses from the charge pump circuit CP. The current pulses vary as a function of a phase and frequency difference between oscillator frequency FO1 of tunable circuit TUC1 and a desired oscillator frequency, which tuning command TC1 defines. The current pulses substantially flow through the feedback path of the amplifier circuit OA. The feedback path, which has a capacitive character, defines a current to voltage conversion with an integrating function. As a result, a current pulse causes a change in tuning voltage VT1. A change in tuning voltage VT1 causes a change in oscillator frequency FO1 of tunable circuit TUC1. In a steady-state situation, tuning voltage VT1 has a value that causes oscillator frequency FO1 to be equal to the desired oscillator frequency, which tuning command TC1 defines.

Tuning control circuit TCC1 sets tuning voltage VT1 to a particular value by means of load current IL1, which flows through load circuit LD1. Let it be assumed that the increased supply voltage VH is equal to 33 volts and that the output impedance of the DC-to-DC converter DCC is equal to 0. Let it further be assumed that tuning control circuit TCC1 sets tuning voltage VT to 25 volts. In that case, load current IL1 will substantially flow through resistances R1, R2. Substantially no current will flow through the diode D1 because the cathode receives a voltage that is well above 5 volts. As a result, the DC-to-DC converter DCC substantially provides load current IL1. Load current IL1 is relatively small because load current IL1 needs to cause a voltage drop of 8 volts across resistances R1, R2.

Let it now be assumed that tuning control circuit TCC1 sets tuning voltage VT1 to 10 volts. Load current IL1 will still substantially flow through resistances R1, R2 because the cathode still receives a voltage that is well above 5 volts. As a result, the DC-to-DC converter DCC substantially provides the load current IL1. Load current IL1 needs to cause a voltage drop of 23 volts across resistances. Accordingly, load current IL1 will be larger than in the case described hereinbefore, where tuning voltage VT1 is set to 25 volts.

Let it now be assumed that tuning control circuit TCC1 sets tuning voltage VT1 to 2 volts. Load current IL1 will substantially flow through resistance R2. A substantial portion of load current IL1 will flow through the diode D1. The diode D1 is conducting. The cathode of the diode D1 will have a voltage that is approximately equal to 5 volts minus a diode junction voltage, which is typically comprised between 0.2 and 0.3 volts. Consequently, there will be voltage drop across resistance R1, which is approximately 28.2 volts. The DC-to-DC converter DCC needs to provide an output current that causes the aforementioned voltage drop. However, this output current is smaller than load current IL1, which the DC-to-DC converter DCC would have to provide if the diode D1 were absent. The aforementioned applies for any value of tuning voltage VT1 in a range comprised between 0 volt and approximately 4.8 volts.

Stated generally, the DC-to-DC converter DCC substantially provides load current IL1 if tuning voltage VT1 is greater than approximately 4.8 volts. Tuning control circuit TCC1 draws a portion of load current IL1 from the main supply voltage VCC1 via the diode D1 if tuning voltage VT is smaller than approximately 4.8 volts. There is a maximum current that the DC-to-DC converter DCC provides to the tuning control circuit TCC1. The maximum current is approximately equal to the increased supply voltage VH minus 4.8 volts divided by the value of resistance R1. Load circuit LD1 prevents tuning control circuit TCC1 from drawing a substantially large current from the DC-to-DC converter DCC if tuning voltage VT1 needs to have a relatively low value. This limits a voltage drop in the increased supply voltage VH, which occurs when tuning voltage VT1 is relatively low, for a given value of the output impedance of the DC-to-DC converter DCC.

FIG. 2B illustrates a measurement of the receiver REC in accordance with the invention illustrated in FIGS. 1 and 3. FIG. 2B is a table, which is similar to the table that FIG. 2A illustrates. The table is obtained while the receiver REC, which FIG. 1 illustrates, operates in the measurement mode, in which tuning control circuit TCC2 is deactivated so that load current IL2 is equal to zero. This means that tuning voltage VT2 is approximately equal to the increased supply voltage VH.

Tunable circuit TUC1 is tuned to the same five different channels A, B, C, D, and E as in FIG. 2A. In case tunable circuit TUC1 is tuned to channel E for which tuning voltage VT1 is 0.3 volt, tuning voltage VT2 has dropped to 25.1 volts only in FIG. 2B, whereas tuning voltage VT2 has dropped to 19.6 volts in FIG. 2A. This means that tunable circuit TUC2 can be tuned to a channel that requires tuning voltage VT2 to have value equal to 25 volt, whereas this is not possible in FIG. 2A, while the DC-to-DC converter DCC is the same.

FIG. 2B thus illustrates that the tuning voltage VT2 can have a relatively high value even when tuning voltage VT1 has a relatively low value, without this necessitating the DC-to-DC converter DCC to have a relatively high power supply capability. As explained hereinbefore, increasing the power supply capability of the DC-to-DC converter DCC entails higher risk of interference or higher cost, or both. The invention prevents the need for increasing the power supply capability, which may otherwise be required in a double tuner receiver REC. The receiver REC in accordance with the invention, which is illustrated in FIGS. 1 and 3, is a double tuner receiver that allows interference-free operation and that can be implemented at relatively low cost.

Load circuit LD2 within the second tuner TUN2 may be similar to load circuit LD1 within the first tuner TUN1. This allows tuning voltage VT1 to have a relatively high value while tuning voltage VT2 has a relatively low value for reasons explained hereinbefore.

### CONCLUDING REMARKS

The detailed description hereinbefore with reference to the drawings illustrates the following characteristics, which are cited in various independent claims. A receiver (REC) comprises two tuners (TUN1, TUN2) and a DC-to-DC converter (DCC) for generating an increased supply voltage (VH) on the basis of a main supply voltage (VCC). Each of the two tuners (TUN1, TUN2) comprises a tunable circuit (TUC1, TUC2), which can be tuned by means of a tuning voltage (VT1, VT2). Each of the two tuners (TUN1, TUN2) further comprises a tuning control circuit (TCC1, TCC2) that is coupled to the DC-to-DC converter (DCC) via a load circuit (LD1, LD2) for generating the tuning voltage (VT1, VT2). The load circuit (LD1) of at least one of the two tuners (TUN1) comprises a branch (D1) coupled to receive the main supply voltage (VCC). The branch (D1) is conductive when the tuning voltage (VT1) is within a voltage range substantially comprised between 0 and the main supply voltage (VCC).

The detailed description hereinbefore further illustrates various optional characteristics, which are cited in the dependent claims. These characteristics may be applied to advantage in combination with the aforementioned characteristics. Various optional characteristics are highlighted in the following paragraphs. Each paragraph corresponds with a particular dependent claim.

The branch (D1) of the load circuit (LD1), which is coupled to receive the main supply voltage (VCC), comprises a diode. This characteristic allows low-cost implementations, because the diode is a relatively cheap element that renders the branch conducting when the tuning voltage is relatively low.

The load circuit (LD1) comprises two resistances (R1, R2) coupled in series so that the two resistances (R1, R2) have a common node. One resistance (R1) has a terminal on which the increased supply voltage (VH) is present. The other resistance (R2) has a terminal on which the tuning voltage (VT1) is present. The diode is coupled to the common node of the two resistances (R1, R2). These characteristics allow the load circuit to be implemented with relatively few components and therefore contribute to cost efficiency.

The two resistances (R1, R2) have respective values in accordance with the following rule: the increased supply voltage (VH) divided by the value of the resistance (R1) having the terminal on which the increased supply voltage (VH) is present is within an order of magnitude of the main supply voltage (VCC) divided by the value of the resistance (R2) having the terminal on which the tuning voltage (VT1) is present. This characteristic allows a smooth load current characteristic which contributes to a satisfactory tuning control behavior.

The aforementioned characteristics can be implemented in numerous different manners. In order to illustrate this, some alternatives are briefly indicated.

The receiver in accordance with the invention may be any type of receiver that comprises a plurality of tuners. A television receiver that is capable of providing a picture-in-picture image is merely an example. As another example, the receiver may be a set-top box with a tuner for receiving a channel that is rendered and another tuner for simultaneously recording another channel. Moreover, one tuner of the receiver may be tunable throughout a particular frequency band, whereas another tuner may be tunable throughout a different frequency band. For example, the invention may be applied in a combined FM/TV receiver. Each tuner may have a specific input. Referring to FIG. 1, the input circuit INP may be replaced by an input circuit dedicated to the first tuner TUN1 and another input circuit dedicated to the second tuner TUN1. It should further be noted that a receiver with two tuners is merely an example. A receiver in accordance with the invention may comprise, for example, three tuners. The DC to DC converter may participate in generating tuning voltages in all three tuners or participate in generating tuning voltages in two tuners only.

The branch of the load circuit that receives the main supply voltage, and which is conductive when the tuning voltage is relatively low, can be implemented in numerous different manners. The detailed description hereinbefore merely provides an example in which a diode forms the branch. As another example, the branch may comprise a switching element, which is rendered conducting when the tuning voltage is relatively low. Referring to FIG. 3, a controllable switch may replace the diode D1. Tuning command TC1 may control the controllable switch, because tuning command TC1 provides an indication of the value of the tuning voltage VT1. As another example, a voltage detection circuit, which receives tuning voltage VT1, may control the controllable switch that replaces the diode D1.

There are numerous ways of implementing functions by means of items of hardware or software, or both. In this respect, the drawings are very diagrammatic, each representing only one possible embodiment of the invention. Thus, although a drawing shows different functions as different blocks, this by no means excludes that a single item of hardware or software carries out several functions. Nor does it exclude that an assembly of items of hardware or software or both carry out a function.

The remarks made herein before demonstrate that the detailed description with reference to the drawings, illustrate rather than limit the invention. There are numerous alternatives, which fall within the scope of the appended claims. Any reference sign in a claim should not be construed as limiting the claim. The word “comprising” does not exclude the presence of other elements or steps than those listed in a claim. The word “a” or “an” preceding an element or step does not exclude the presence of a plurality of such elements or steps.

1. A receiver comprising two and a DC-to-DC converter for generating an increased supply voltage on the basis of a main supply voltage, each of the two comprising a tunable circuit, which can be tuned by means of a tuning voltage, and a tuning control circuit that is coupled to the DC-to-DC converter via a load circuit for generating the tuning voltage the load circuit of at least one of the two tuners comprising a branch coupled to receive the main supply voltage, the branch being conductive when the tuning voltage is within a voltage range substantially comprised between 0 and the main supply voltage.

2. A receiver according to claim 1, the branch of the load circuit, which is coupled to receive the main supply voltage, comprising a diode.

3. A receiver according to claim 2, the load circuit comprising two resistances coupled in series so that the two resistances have a common node, one resistance having a terminal on which the increased supply voltage is present and the other resistance having a terminal on which the tuning voltage is present, the diode being coupled to the common node of the two resistances.

4. A receiver according to claim 3, the two resistances having respective values in accordance with the following rule: the increased supply voltage divided by the value of the resistance having the terminal on which the increased supply voltage is present is within an order of magnitude of the main supply voltage divided by the value of the resistance having the terminal on which the tuning voltage is present.

5. A method of tuning a receiver that comprises two tuners and a DC-to-DC converter for generating an increased supply voltage on the basis of a main supply voltage, each of the two tuners comprising a tunable circuit, which can be tuned by means of a tuning voltage, and a tuning control circuit that is coupled to the DC-to-DC converter via a load circuit for generating the tuning voltage, the load circuit of at least one of the two tuners comprising a branch coupled to receive the main supply voltage,
the method comprising a control step in which the branch is rendered conducting when the tuning voltage is within a voltage range substantially comprised between 0 and the main supply voltage.

6. An audiovisual set comprising a rendering device for rendering an audiovisual signal, and a receiver according to claim 1 for deriving the audiovisual signal from a radio frequency spectrum.
